(19) United States
(12) Patent Application Publication
(10) Pub. No.: US 2016/0284881 A1
(43) Pub. Date: Sep. 29, 2016

(54) Solar Cell having Epitaxial Passivation Layer

(71) Applicants: Michael C. Johnson, Alameda, CA (US); David D. Smith, Campbell, CA (US); Seung Bum Rim, Palo Alto, CA (US)

(72) Inventors: Michael C. Johnson, Alameda, CA (US); David D. Smith, Campbell, CA (US); Seung Bum Rim, Palo Alto, CA (US)

(21) Appl. No.: 14/665,702

(22) Filed: Mar. 23, 2015

(51) Int. Cl. H01L 31/0216; H01L 31/0687; H01L 31/0368; H01L 31/0336

(52) U.S. Cl. CPC H01L 31/02167; H01L 31/0336; H01L 31/0687; H01L 31/03682

(57) ABSTRACT

Solar cells having epitaxial passivation layers are described. In an example, a solar cell includes a crystalline substrate. An epitaxial passivation layer is disposed directly on the crystalline substrate. A plurality of alternating N-type and P-type emitter regions is disposed on the epitaxial passivation layer.

### TECHNICAL FIELD

Embodiments of the present disclosure are in the field of renewable energy and, in particular, solar cells having epitaxial passivation layers.

### BACKGROUND

Photovoltaic cells, commonly known as solar cells, are well known devices for direct conversion of solar radiation into electrical energy. Generally, solar cells are fabricated on a semiconductor wafer or substrate using semiconductor processing techniques to form a p-n junction near a surface of the substrate. Solar radiation impinging on the surface of, and entering into, the substrate creates electron and hole pairs in the bulk of the substrate. The electron and hole pairs migrate to p-doped and n-doped regions in the substrate, thereby generating a voltage differential between the doped regions. The doped regions are connected to conductive regions on the solar cell to direct an electrical current from the cell to an external circuit coupled thereto.

Efficiency is an important characteristic of a solar cell as it is directly related to the capability of the solar cell to generate power. Likewise, efficiency in producing solar cells is directly related to the cost effectiveness of such solar cells. Accordingly, techniques for increasing the efficiency of solar cells, or techniques for increasing the efficiency in the manufacture of solar cells, are generally desirable. Some embodiments of the present disclosure allow for increased solar cell manufacture efficiency by providing novel processes for fabricating solar cell structures. Some embodiments of the present disclosure allow for increased solar cell efficiency by providing novel solar cell structures.

### BRIEF DESCRIPTION OF THE DRAWINGS

FIG. 1A illustrates a cross-sectional view of a solar cell having an epitaxial passivation layer disposed directly on a crystalline substrate, in accordance with an embodiment of the present disclosure.

FIG. 1B illustrates a cross-sectional view of the solar cell of FIG. 1A having a contact structure formed thereon, in accordance with an embodiment of the present disclosure.

FIG. 1C is an energy band diagram for electrons as a function of position for an exemplary epitaxial GaP passivation layer as applied to the structure of FIG. 1A, in accordance with an embodiment of the present disclosure.

FIG. 1D is an energy band diagram for holes as a function of position for an exemplary epitaxial GaP passivation layer as applied to the structure of FIG. 1A, in accordance with an embodiment of the present disclosure.

FIG. 2A illustrates a cross-sectional view of another solar cell having an epitaxial passivation layer disposed directly on a crystalline substrate, in accordance with an embodiment of the present disclosure.

FIG. 2B illustrates a cross-sectional view of the solar cell of FIG. 2A having a contact structure formed thereon, in accordance with an embodiment of the present disclosure.

FIG. 2C is an energy band diagram for holes as a function of position for an exemplary epitaxial GaP passivation layer as applied to the structure of FIG. 2A, in accordance with an embodiment of the present disclosure.

FIG. 2D is an energy band diagram for electrons as a function of position for an exemplary epitaxial GaP passivation layer as applied to the structure of FIG. 2A, in accordance with an embodiment of the present disclosure.

FIG. 3A illustrates a cross-sectional view of a solar cell having an epitaxial passivation layer included in a differentiated emitter region architecture, in accordance with an embodiment of the present disclosure.

FIG. 3B illustrates a cross-sectional view of the solar cell of FIG. 3A having a contact structure formed thereon, in accordance with an embodiment of the present disclosure.

FIG. 3C is an energy band diagram for holes as a function of position for an exemplary epitaxial GaP passivation layer as applied to the structure of FIG. 3A, in accordance with an embodiment of the present disclosure.

FIG. 3D is an energy band diagram for electrons as a function of position for an exemplary epitaxial GaP passivation layer as applied to the structure of FIG. 3A, in accordance with an embodiment of the present disclosure.

FIG. 4A illustrates a cross-sectional view of a solar cell having a selectively doped epitaxial passivation layer, in accordance with an embodiment of the present disclosure.

FIG. 4B illustrates a cross-sectional view of the solar cell of FIG. 4A having a contact structure formed thereon, in accordance with an embodiment of the present disclosure.

FIG. 4C is an energy band diagram for holes as a function of position for an exemplary epitaxial GaP passivation layer as applied to the structure of FIG. 4A, in accordance with an embodiment of the present disclosure.

FIG. 4D is an energy band diagram for electrons as a function of position for an exemplary epitaxial GaP passivation layer as applied to the structure of FIG. 4A, in accordance with an embodiment of the present disclosure.

### DETAILED DESCRIPTION

The following detailed description is merely illustrative in nature and is not intended to limit the embodiments of the subject matter or the application and uses of such embodiments. As used herein, the word “exemplary” means “serving as an example, instance, or illustration.” Any implementation described herein as exemplary is not necessarily to be construed as preferred or advantageous over other implementations. Furthermore, there is no intention to be bound by any expressed or implied theory presented in the preceding technical field, background, brief summary or the following detailed description.

This specification includes references to “one embodiment” or “an embodiment.” The appearances of the phrases “in one embodiment” or “in an embodiment” do not necessarily refer to the same embodiment. Particular features, structures, or characteristics may be combined in any suitable manner consistent with this disclosure.

Terminology. The following paragraphs provide definitions and/or context for terms found in this disclosure (including the appended claims):

“Comprising.” This term is open-ended. As used in the appended claims, this term does not foreclose additional structure or steps.

“Configured To.” Various units or components may be described or claimed as “configured to” perform a task or tasks. In such contexts, “configured to” is used to connote structure by indicating that the units/components include structure that performs those task or tasks during operation. As such, the unit/component can be said to be configured to perform the task even when the specified unit/component is not currently operational (e.g., is not on/active). Reciting that a unit/circuit/component is “configured to” perform one or more tasks is expressly intended not to invoke 35 U.S.C. §112, sixth paragraph, for that unit/component.

“First,” “Second,” etc. As used herein, these terms are used as labels for nouns that they precede, and do not imply any type of ordering (e.g., spatial, temporal, logical, etc.). For example, reference to a “first” solar cell does not necessarily imply that this solar cell is the first solar cell in a sequence; instead the term “first” is used to differentiate this solar cell from another solar cell (e.g., a “second” solar cell).

“Coupled”—The following description refers to elements or nodes or features being “coupled” together. As used herein, unless expressly stated otherwise, “coupled” means that one element/node/feature is directly or indirectly joined to (or directly or indirectly communicates with) another element/node/feature, and not necessarily mechanically.

In addition, certain terminology may also be used in the following description for the purpose of reference only, and thus are not intended to be limiting. For example, terms such as “upper”, “lower”, “above”, and “below” refer to directions in the drawings to which reference is made. Terms such as “front”, “back”, “rear”, “side”, “outboard”, and “inboard” describe the orientation and/or location of portions of the component within a consistent but arbitrary frame of reference which is made clear by reference to the text and the associated drawings describing the component under discussion. Such terminology may include the words specifically mentioned above, derivatives thereof, and words of similar import.

“Inhibit”—As used herein, inhibit is used to describe a reducing or minimizing effect. When a component or feature is described as inhibiting an action, motion, or condition it may completely prevent the result or outcome or future state completely. Additionally, “inhibit” can also refer to a reduction or lessening of the outcome, performance, and/or effect which might otherwise occur. Accordingly, when a component, element, or feature is referred to as inhibiting a result or state, it need not completely prevent or eliminate the result or state.

Solar cells having epitaxial passivation layers are described herein. In the following description, numerous specific details are set forth, such as specific material compositions, in order to provide a thorough understanding of embodiments of the present disclosure. It will be apparent to one skilled in the art that embodiments of the present disclosure may be practiced without these specific details. In other instances, well-known fabrication techniques, such as lithography and patterning techniques, are not described in detail in order to not unnecessarily obscure embodiments of the present disclosure. Furthermore, it is to be understood that the various embodiments shown in the figures are illustrative representations and are not necessarily drawn to scale.

Disclosed herein are solar cells. In an embodiment, a solar cell includes a crystalline substrate. An epitaxial passivation layer is disposed directly on the crystalline substrate. A plurality of alternating N-type and P-type emitter regions is disposed on the epitaxial passivation layer. In one such embodiment, the plurality of alternating N-type and P-type emitter regions is a plurality of alternating N-type and P-type semiconductor material regions. In another such embodiment, the plurality of alternating N-type and P-type emitter regions is a plurality of alternating N-type and P-type metal regions.

In another embodiment, a solar cell includes a crystalline substrate. A first plurality of emitter regions of a first conductivity type is disposed on a surface of the crystalline substrate. Each of the first plurality of emitter regions includes a doped polycrystalline silicon region disposed on an amorphous dielectric layer. A second plurality of emitter regions of a second conductivity type is disposed on the surface of the crystalline substrate and alternates with the first plurality of emitter regions. Each of the second plurality of emitter regions includes a doped epitaxial material layer disposed directly on the crystalline substrate.

In another embodiment, a solar cell includes a crystalline substrate. An epitaxial passivation layer is disposed directly on the crystalline substrate. A plurality of alternating N-type and P-type emitter regions is disposed in the epitaxial passivation layer.

One or more embodiments described herein are directed to solar cells incorporating III-V material epitaxial passivation. Utilization of epitaxially grown materials can provide better passivation and improve emitter properties as compared with a standard tunnel oxide/polycrystalline silicon structure. Epitaxial growth may allow for improved passivation versus thermal oxide passivation. In addition, by tailoring the properties of the epitaxial material, the tunneling effects and collection properties of the associated emitter regions can be improved. Described herein are at least four structural types applicable to one or both of interdigitated back contact (IBC) or front contact solar cells.

To provide context, a passivated contact strategy typically requires that a principal surface passivation be carried out by thermal oxide formation. However, such an oxide must be thin (e.g., less than approximately 15 Angstroms) to allow a tunneling regime for collection of the respective carriers. The characteristics for such a material can suffer due to processing drifts and errors which manifest in decreased efficiency and reliability. In addition, the passivation can be limited due to imperfect oxidation and lack of barrier abilities to the dopant materials. There is need for improved passivation, improved tunneling properties, improved barrier properties, and improved emitter functionality which, in an embodiment, may be realized using tailored epitaxial materials on Si.

In accordance with one or more embodiments described herein, employing epitiaxial growth such as GaP, AlGaP, GaAs, InGaAs, or other III-V materials on Si(100) (or 110 or 111) can be used in a number of different structures to improve IBC solar cell efficiency and performance. As described below, there are at least four major structures which can be improved by epitaxial passivated growth that can improve and simplify process flows. For example, in an embodiment, a thin epitaxial layer is deposited as a tunneling layer prior to a process flow for fabricating polysilicon emitters. Such an approach can allow for better passivation by minimizing dangling bonds on the device/Si interface as well as may allow for improved dopant barrier. Improved tunneling effects may also be achieved by minimizing minority carrier barrier in the valence band allowing for a more robust process flow as thickness of the epitaxial layer can be increased. In another embodiment, an epitaxial material is tailored as an intrinsic layer and metal contacts are used to adjust Fermi levels to determine polarity collection. Such an approach may allow for a drastically reduced process flow and improved collection efficiency. In another embodiment, a doped epitaxial material is used as an N-type emitter and surface passivation layer in a hybrid material architecture process flow. In another embodiment, doped and/or in-situ doped epitaxial material is used as a passivation material and an emitter material. Such an epitaxial grown material may be doped N-type and P-type, respectively, to fabricate the emitter features on the device. Barrier width can be controlled by dopant incorporation allowing tunneling property control.

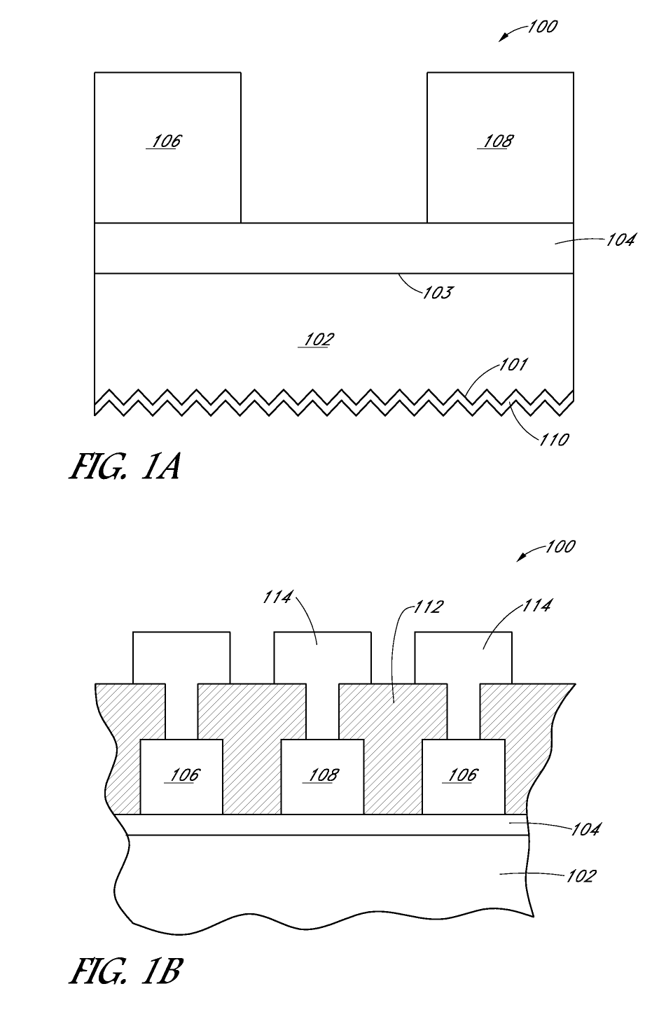

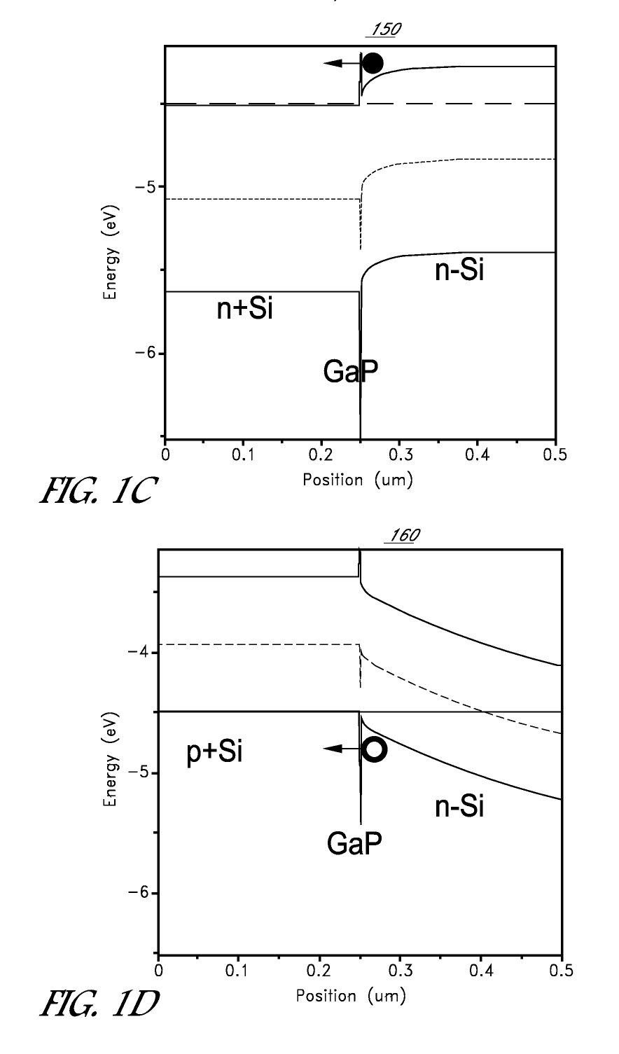

In a first aspect, an amorphous tunnel oxide layer of a conventional interdigitated back contact solar cell can effectively be replaced by an epitaxial passivation layer. As an example, FIG. 1A illustrates a cross-sectional view of a solar cell having an epitaxial passivation layer disposed directly on a crystalline substrate, in accordance with an embodiment of the present disclosure.

Referring to FIG. 1A, a portion of a solar cell 100 includes a crystalline substrate 102 having a light-receiving surface 101 and a back surface 103. An epitaxial passivation layer 104 is disposed directly on the back surface 103 of the crystalline substrate 102. A plurality of alternating N-type 106 and P-type 108 emitter regions is disposed on the epitaxial passivation layer 104. In one such embodiment, the plurality of alternating N-type 106 and P-type 108 emitter regions is a plurality of alternating N-type and P-type semiconductor material regions.

In an embodiment, the crystalline substrate 102 is a monocrystalline silicon substrate, such as a bulk single crystalline N-type doped silicon substrate. The global crystal orientation at the surface of the substrate 102 may be, e.g., (100), (110) or (111). It is to be appreciated, however, that crystalline substrate 102 may be a layer, such as a multi-crystalline silicon layer, disposed on a global solar cell substrate.

In an embodiment, the epitaxial passivation layer 104 is an epitaxial III-V material layer. In one such embodiment, the epitaxial III-V material layer is a material such as, but not limited to, gallium phosphide (GaP), aluminum gallium phosphide (AlGaP), gallium arsenide (GaAs), indium gallium arsenide (InGaAs), gallium nitride (GaN) or aluminum gallium nitride (AlGaN). In an embodiment, the epitaxial passivation layer 104 is a continuous layer across a global surface (e.g., across surface 103) of the crystalline substrate 102, as is depicted in FIG. 1A. In another embodiment, although not depicted, the epitaxial passivation layer 104 is a patterned layer substantially aligned with a pattern of the plurality of alternating N-type 106 and P-type 108 emitter regions. In an embodiment, the epitaxial passivation layer 104 is epitaxial with a single crystalline silicon substrate 102 having a crystal orientation such as, but not limited to, (100), (110), or (111). In an embodiment, the epitaxial passivation layer is formed by chemical vapor deposition (CVD), physical vapor deposition (PVD) or molecular beam epitaxy (MBE) which may be thermally treated to improve epitaxial properties.

In an embodiment, the epitaxial passivation layer 104 is a mono- or single-crystalline layer. In other embodiments, however, the epitaxial passivation layer 104 is a multi- or poly-crystalline epitaxial layer. In an embodiment, the epitaxial layer 104 has a thickness of approximately three times the thickness of a corresponding tunnel dielectric layer, e.g., the epitaxial passivation layer 104 has a thickness of approximately 50 Angstroms. In an embodiment, the epitaxial passivation layer 104 is an undoped or intrinsic layer.

In an embodiment, the plurality of alternating N-type 106 and P-type 108 semiconductor material regions is a plurality of alternating phosphorous-doped polycrystalline silicon and boron-doped polycrystalline silicon regions. In one such embodiment, the alternating N-type and P-type polycrystalline silicon regions are formed by, e.g., using a plasma-enhanced chemical vapor deposition (PECVD) process.

Referring again to FIG. 1A, in an embodiment, the light-receiving surface 101 is texturized. In an embodiment, a hydroxide-based wet etchant is employed to texturize the light receiving surface 101 of the crystalline substrate 102. In one embodiment, a texturized surface may be one which has a regular or an irregular shaped surface for scattering incoming light, decreasing the amount of light reflected off of the light receiving surface 101 of the solar cell. Referring again to FIG. 1A, additional embodiments can include formation of a passivation and/or anti-reflective coating (ARC) layers (shown collectively as layer 110) on the light-receiving surface 101.

It is to be appreciated that additional layers may be formed above the structure of FIG. 1A. As an example, FIG. 1B illustrates a cross-sectional view of the solar cell of FIG. 1A having a contact structure formed thereon, in accordance with an embodiment of the present disclosure. Referring to FIG. 1B, the solar cell 100 may further include a patterned anti-reflective coating layer 112 formed on the alternating N-type 106 and P-type 108 emitter regions and on the exposed portions of the epitaxial passivation layer 104. In one such embodiment, the anti-reflective coating layer 112 may be a layer of silicon nitride (SiN) or a layer of amorphous silicon/silicon nitride (a-Si/SiN), either of which may provide improved passivation for the interface between the crystalline substrate 102 and the epitaxial passivation layer 104.

Referring again to FIG. 1B, in an embodiment, conductive contacts 114 are formed in the patterned anti-reflective coating layer 112 and electrically contact the alternating N-type 106 and P-type 108 emitter regions. In one such embodiment, the conductive contacts 114 are formed by first forming a metal seed layer and then electroplating a metal such as copper in a mask formed on the metal seed layer. In another embodiment, the conductive contacts 114 are formed by a printed paste process, such as a printed silver paste process. The resulting structure of FIG. 1B can be viewed as a completed or almost completed solar cell, which may be included in a solar module.

Energy band diagrams may be used to represent the effect of including an epitaxial passivation layer in the structure of FIG. 1A. As an example, FIG. 1C is an energy band diagram 150 for electrons as a function of position for an exemplary epitaxial intrinsic GaP (i-GaP) passivation layer as applied to the structure of FIG. 1A, in accordance with an embodiment of the present disclosure. FIG. 1D is an energy band diagram 160 for holes as a function of position for an exemplary epitaxial GaP passivation layer as applied to the structure of FIG. 1A, in accordance with an embodiment of the present disclosure.

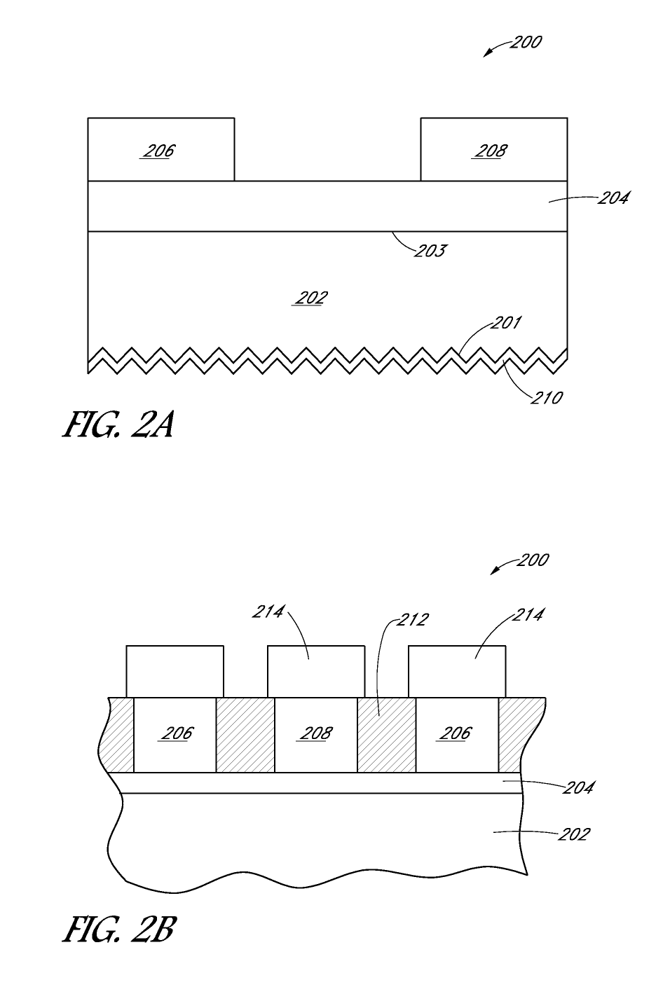

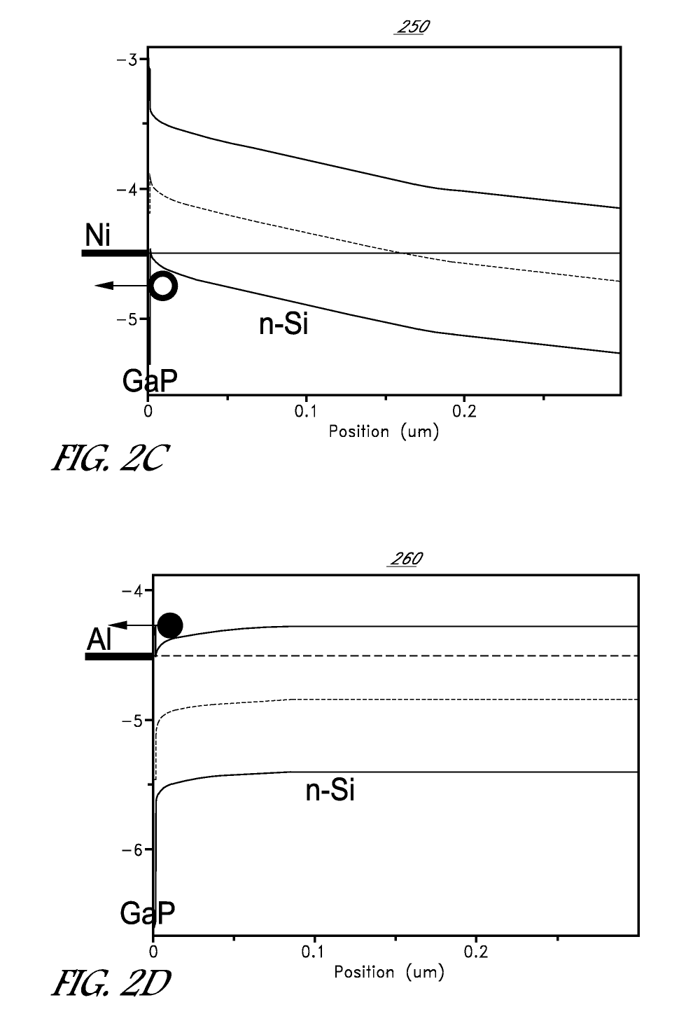

In line with the above first aspect, metal Fermi level tailoring to form emitter regions is described. As an example, FIG. 2A illustrates a cross-sectional view of another solar cell having an epitaxial passivation layer disposed directly on a crystalline substrate, in accordance with an embodiment of the present disclosure.

Referring to FIG. 2A, a portion of a solar cell 200 includes a crystalline substrate 202 having a light-receiving surface 201 and a back surface 203. An epitaxial passivation layer 204 is disposed directly on the back surface 203 of the crystalline substrate 202. A plurality of alternating N-type 206 and P-type 208 emitter regions is disposed on the epitaxial passivation layer 204. In one such embodiment, the plurality of alternating N-type 206 and P-type 208 emitter regions is a plurality of alternating N-type and P-type metal regions.

In an embodiment, the crystalline substrate 202 is a monocrystalline silicon substrate, such as a bulk single crystalline N-type doped silicon substrate. The global crystal orientation at the surface of the substrate 202 may be, e.g., (100), (110) or (111). It is to be appreciated, however, that crystalline substrate 202 may be a layer, such as a multi-crystalline silicon layer, disposed on a global solar cell substrate.

In an embodiment, the epitaxial passivation layer 204 is an epitaxial III-V material layer. In one such embodiment, the epitaxial III-V material layer is a material such as, but not limited to, gallium phosphide (GaP), aluminum gallium phosphide (AlGaP), gallium arsenide (GaAs), indium gallium arsenide (InGaAs), gallium nitride (GaN) or aluminum gallium nitride (AlGaN). In an embodiment, the epitaxial passivation layer 204 is a continuous layer across a global surface (e.g., across surface 203) of the crystalline substrate 202, as is depicted in FIG. 2A. In another embodiment, although not depicted, the epitaxial passivation layer 204 is a patterned layer substantially aligned with a pattern of the plurality of alternating N-type 206 and P-type 208 emitter regions. In an embodiment, the epitaxial passivation layer 204 is epitaxial with a single crystalline silicon substrate 202 having a crystal orientation such as, but not limited to, (100), (110), or (111). In an embodiment, the epitaxial passivation layer 204 is formed by chemical vapor deposition (CVD), physical vapor deposition (PVD) or molecular beam epitaxy (MBE) which may be thermally treated to improve epitaxial properties.

In an embodiment, the epitaxial passivation layer 204 is a mono- or single-crystalline layer. In other embodiments, however, the epitaxial passivation layer 204 is a multi- or poly-crystalline epitaxial layer. In an embodiment, the epitaxial layer 204 has a thickness of approximately three times the thickness of a corresponding tunnel dielectric layer, e.g., the epitaxial passivation layer 204 has a thickness of approximately 50 Angstroms. In an embodiment, the epitaxial passivation layer 204 is an undoped or intrinsic layer.

In an embodiment, the plurality of alternating N-type 206 and P-type 208 metal regions is a plurality of alternating aluminum (Al) and nickel (Ni) regions. In another embodiment, the plurality of alternating N-type 206 and P-type 208 metal regions is a plurality of alternating aluminum (Al) and platinum (Pt) or nickel (Ni) regions.

Referring again to FIG. 2A, in an embodiment, the light-receiving surface 201 is texturized. In an embodiment, a hydroxide-based wet etchant is employed to texturize the light receiving surface 201 of the crystalline substrate 202. In one embodiment, a texturized surface may be one which has a regular or an irregular shaped surface for scattering incoming light, decreasing the amount of light reflected off of the light receiving surface 201 of the solar cell. Referring again to FIG. 2A, additional embodiments can include formation of a passivation and/or anti-reflective coating (ARC) layers (shown collectively as layer 210) on the light-receiving surface 201.

It is to be appreciated that additional layers may be formed above the structure of FIG. 2A. As an example, FIG. 2B illustrates a cross-sectional view of the solar cell of FIG. 2A having a contact structure formed thereon, in accordance with an embodiment of the present disclosure. Referring to FIG. 2B, the solar cell 200 may further include a patterned anti-reflective coating layer 212 formed on the alternating N-type 206 and P-type 208 emitter regions and on the exposed portions of the epitaxial passivation layer 204. In one such embodiment, the anti-reflective coating layer 212 may be a layer of silicon nitride (SiN) or a layer of amorphous silicon/silicon nitride (a-Si/SiN), either of which may provide improved passivation for the interface between the crystalline substrate 202 and the epitaxial passivation layer 204.

Referring again to FIG. 2B, in an embodiment, conductive contacts 214 are formed in the patterned anti-reflective coating layer 212 and electrically contact the alternating N-type 206 and P-type 208 emitter regions. In one such embodiment, the conductive contacts 212 are formed by first forming a metal seed layer and then electroplating a metal such as copper in a mask formed on the metal seed layer. In another embodiment, the conductive contacts 214 are formed by a printed paste process, such as a printed silver paste process. The resulting structure of FIG. 2B can be viewed as a completed or almost completed solar cell, which may be included in a solar module.

Energy band diagrams may be used to represent the effect of including an epitaxial passivation layer in the structure of FIG. 2A. As an example, FIG. 2C is an energy band diagram 250 for holes as a function of position for an exemplary epitaxial intrinsic GaP (i-GaP) passivation layer as applied to the structure of FIG. 2A, in accordance with an embodiment of the present disclosure. FIG. 2D is an energy band diagram 260 for electrons as a function of position for an exemplary epitaxial intrinsic GaP (i-GaP) passivation layer as applied to the structure of FIG. 2A, in accordance with an embodiment of the present disclosure.

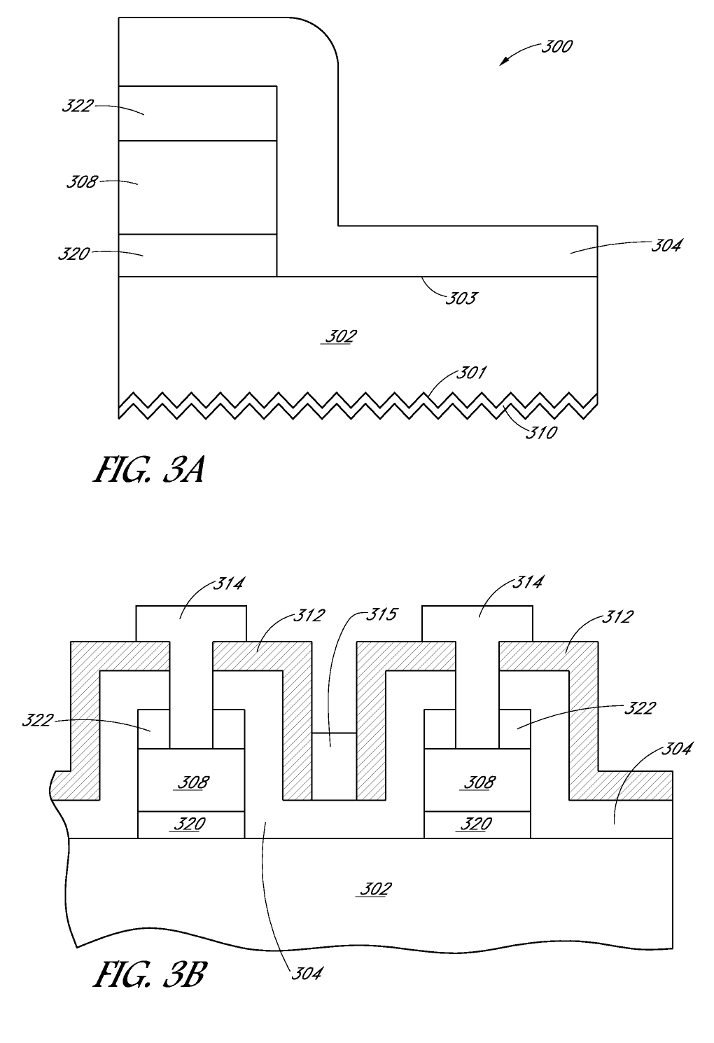

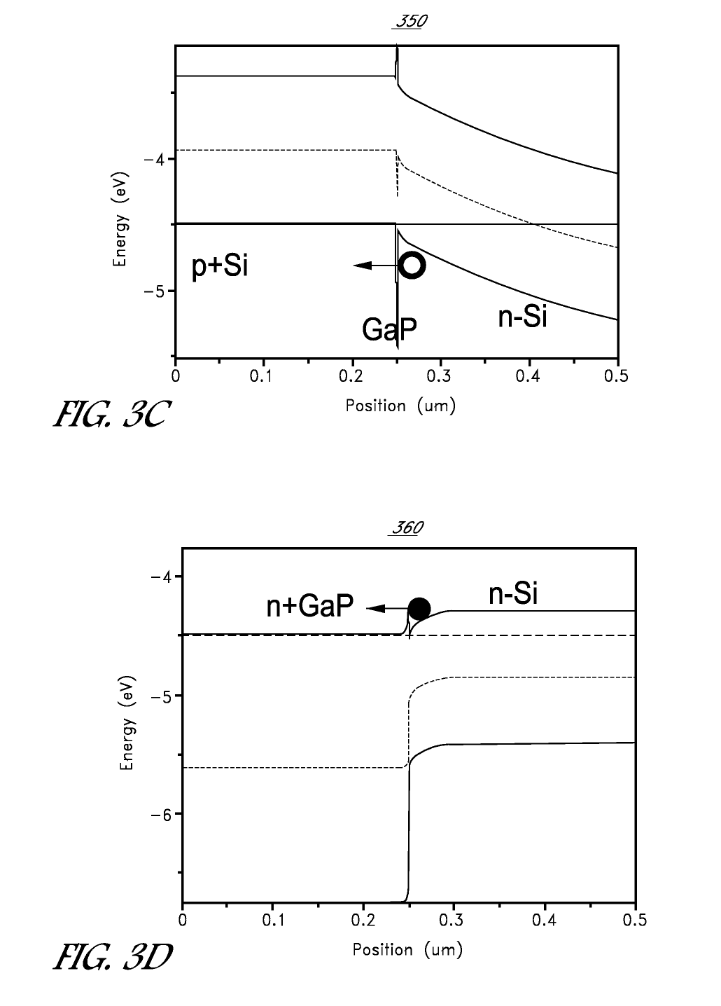

In a second aspect, a solar cell having different structural types for N-type and P-type emitter regions may be fabricated to include an epitaxial passivation layer. As an example, FIG. 3A illustrates a cross-sectional view of a solar cell having an epitaxial passivation layer included in a differentiated emitter region architecture, in accordance with an embodiment of the present disclosure.

Referring to FIG. 3A, a portion of a solar cell 300 includes a crystalline substrate 302 having a light-receiving surface 301 and a back surface 303. A first plurality of emitter regions of a first conductivity type (one such region shown as pairing 308/320) is disposed on the surface 303 of the crystalline substrate 302. Each of the first plurality of emitter regions 308/320 includes a doped polycrystalline silicon region 308 disposed on an amorphous dielectric layer 320. A second plurality of emitter regions of a second conductivity type (one such regions is shown as the portion of 304 on substrate 302) is disposed on the surface 303 of the crystalline substrate 302 and alternates with the first plurality of emitter regions. Each of the second plurality of emitter regions includes a doped epitaxial material layer 304 disposed directly on the crystalline substrate 302. Since the emitter regions based on the doped epitaxial layer 304 (second emitter region type) have a different structure than the emitter regions based on a doped polycrystalline silicon region 308/amorphous dielectric layer 320 stack, the solar cell may be referred to as a hybrid or differentiated architecture type solar cell.

In an embodiment, the doped polycrystalline silicon region 308 of each of the first plurality of emitter regions includes P-type doped polycrystalline silicon, and the doped epitaxial material layer 304 is an N-type doped epitaxial material layer. In another embodiment, the doped polycrystalline silicon region 308 of each of the first plurality of emitter regions includes N-type doped polycrystalline silicon, and the doped epitaxial material layer 304 is a P-type doped epitaxial material layer. Referring again to FIG. 3A, in an embodiment, the doped epitaxial material layer 304 is a continuous layer and is further disposed over the first plurality of emitter regions. In one such embodiment, an insulating layer 322, such as a BSG or PSG layer used to dope region 308, is retained on region 308 as an intervening layer between region 308 and the doped epitaxial material layer 304.

In an embodiment, the doped epitaxial material layer 304 is a doped epitaxial III-V material layer. In one such embodiment, the doped epitaxial III-V material layer is a doped material such as, but not limited to, a doped GaP, AlGaP, GaAs, InGaAs, GaN or AlGaN layer. In an embodiment, the doped epitaxial material layer 304 is N-type doped with phosphorous. In another embodiment, the doped epitaxial material layer 304 is P-type doped with boron. In an embodiment, the doped epitaxial passivation layer 304 is formed by chemical vapor deposition (CVD), physical vapor deposition (PVD) or molecular beam epitaxy (MBE). In an embodiment, the doped epitaxial passivation layer 304 is a mono- or single-crystalline layer. In other embodiments, however, the doped epitaxial passivation layer 304 is a multi- or poly-crystalline epitaxial layer. In an embodiment, the doped epitaxial layer 304 has a thickness of approximately 50-1000 Angstroms.

In an embodiment, the thin dielectric layer 320 is a tunneling silicon oxide layer having a thickness of approximately 2 nanometers or less. In one such embodiment, the term “tunneling dielectric layer” refers to a very thin dielectric layer, through which electrical conduction can be achieved. The conduction may be due to quantum tunneling and/or the presence of small regions of direct physical connection through thin spots in the dielectric layer. In one embodiment, the tunneling dielectric layer is or includes a thin silicon oxide layer.

Referring again to FIG. 3A, in an embodiment, the light-receiving surface 301 is texturized. In an embodiment, a hydroxide-based wet etchant is employed to texturize the light receiving surface 301 of the crystalline substrate 302. In one embodiment, a texturized surface may be one which has a regular or an irregular shaped surface for scattering incoming light, decreasing the amount of light reflected off of the light receiving surface 301 of the solar cell. Referring again to FIG. 3A, additional embodiments can include formation of a passivation and/or anti-reflective coating (ARC) layers (shown collectively as layer 310) on the light-receiving surface 301.

It is to be appreciated that additional layers may be formed above the structure of FIG. 3A. As an example, FIG. 3B illustrates a cross-sectional view of the solar cell of FIG. 3A having a contact structure formed thereon, in accordance with an embodiment of the present disclosure. Referring to FIG. 3B, the solar cell 300 may further include a patterned anti-reflective coating layer 312 formed on the emitter regions. In one such embodiment, the anti-reflective coating layer 312 may be a layer of silicon nitride (SiN) or a layer of amorphous silicon/silicon nitride (a-Si/SiN), either of which may provide improved passivation for the interface between the crystalline substrate 302 and the doped epitaxial passivation layer 304.

Referring again to FIG. 3B, in an embodiment, conductive contacts 314 and 315 are formed in the patterned anti-reflective coating layer 312 and electrically contact the alternating emitter regions. In one such embodiment, the conductive contacts 314 are P-type metal contacts (e.g., nickel or platinum) electrically contacting P-type polycrystalline based regions 308, while the conductive contacts 315 are N-type metal contacts (e.g., aluminum) electrically contacting N-type doped epitaxial passivation layer 304. In another embodiment, the conductive contacts 314 are N-type metal contacts (e.g., aluminum) electrically contacting N-type polycrystalline based regions 308, while the conductive contacts 315 are P-type metal contacts (e.g., nickel or platinum) electrically contacting P-type doped epitaxial passivation layer 304. The resulting structure of FIG. 3B can be viewed as a completed or almost completed solar cell, which may be included in a solar module.

Energy band diagrams may be used to represent the effect of including an epitaxial passivation layer in the structure of FIG. 3A. As an example, FIG. 3C is an energy band diagram 350 for holes as a function of position for an exemplary epitaxial GaP passivation layer as applied to the structure of FIG. 3A, in accordance with an embodiment of the present disclosure. FIG. 3D is an energy band diagram 360 for electrons as a function of position for an exemplary epitaxial GaP passivation layer as applied to the structure of FIG. 3A, in accordance with an embodiment of the present disclosure.

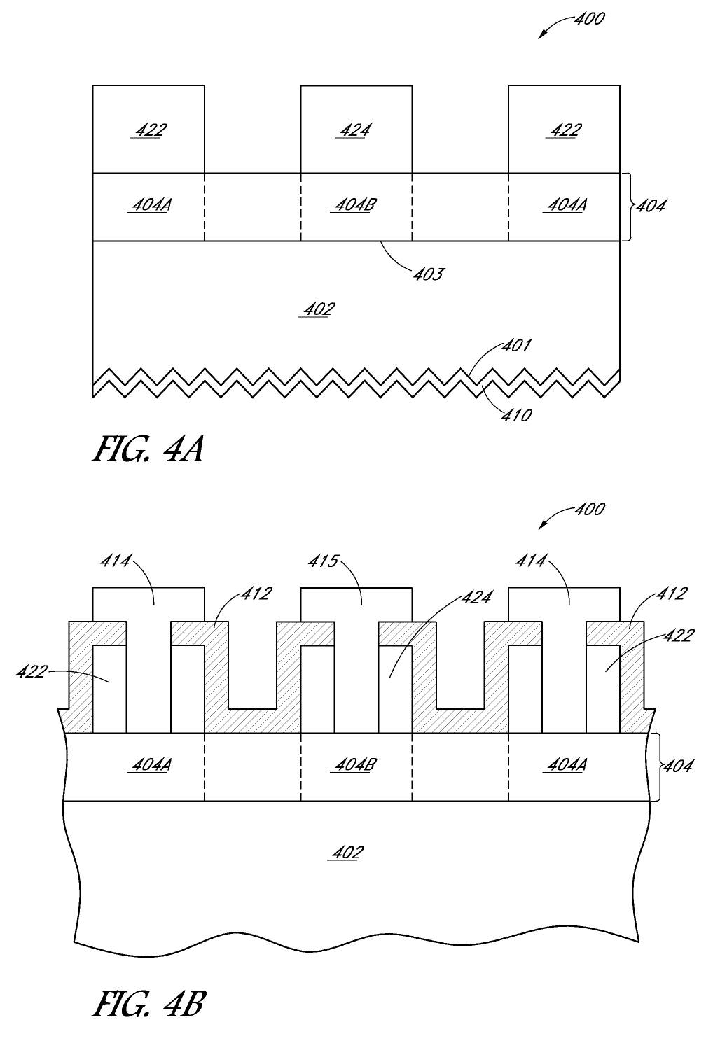

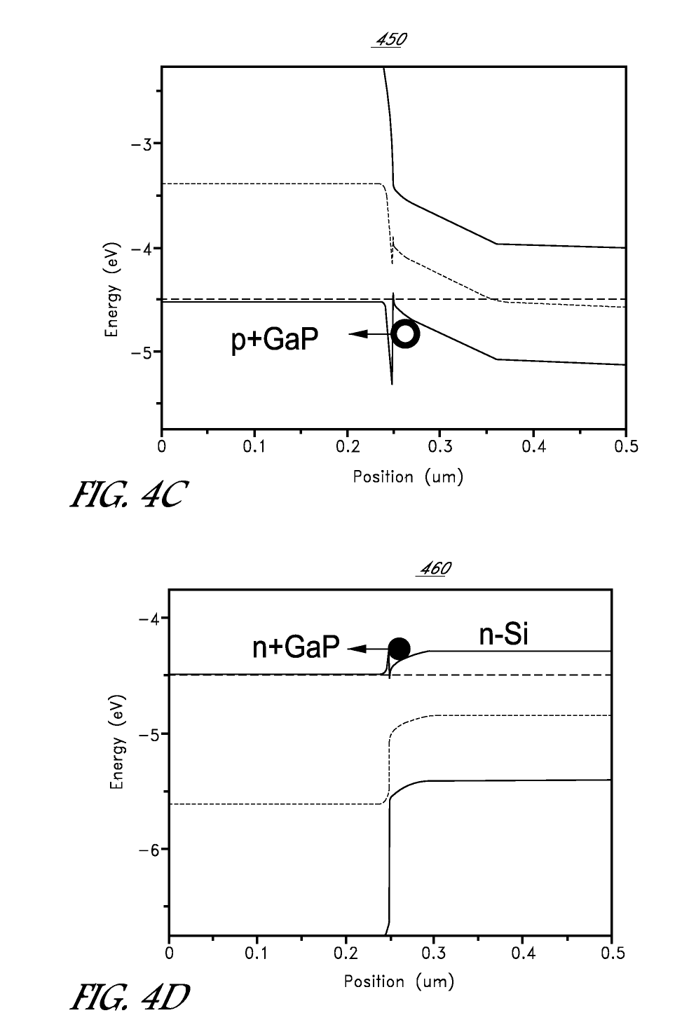

In a third aspect, a selectively doped epitaxial material passivation layer is incorporated to provide emitter regions for a solar cell. As an example, FIG. 4A illustrates a cross-sectional view of a solar cell having a selectively doped epitaxial passivation layer, in accordance with an embodiment of the present disclosure.

Referring to FIG. 4A, a portion of a solar cell 400 includes a crystalline substrate 402 having a light-receiving surface 401 and a back surface 403. An epitaxial passivation layer 404 is disposed directly on the back surface 403 of the crystalline substrate 402. A plurality of alternating N-type 404A and P-type 404B emitter regions is disposed in the epitaxial passivation layer 404.

In an embodiment, the epitaxial material layer 404 is an epitaxial III-V material layer. In one such embodiment, the epitaxial III-V material layer is a material such as, but not limited to, a GaP, AlGaP, GaAs, InGaAs, GaN or AlGaN layer. In an embodiment, the doped N-type portions 404A of the epitaxial material layer 404 are N-type doped with phosphorous, and the doped P-type portions 404B of the epitaxial material layer 404 are P-type doped with boron. It is to be appreciated, however, that other dopants such as Si (for N-Type) or Mg (for P-type) may be used. In an embodiment, the epitaxial passivation layer 404 is formed by chemical vapor deposition (CVD), physical vapor deposition (PVD) or molecular beam epitaxy (MBE). Regions of the epitaxial passivation layer 404 may then be doped, e.g., with a patterned PSG layer 422 and a patterned BSG layer 424 to form N-type and P-type regions, respectively, as is depicted in FIG. 4A. In an embodiment, the epitaxial passivation layer 404 is a mono- or single-crystalline layer. In other embodiments, however, the epitaxial passivation layer 404 is a multi- or poly-crystalline epitaxial layer. In an embodiment, the epitaxial layer 404 has a thickness of approximately 50 Angstroms. In an embodiment, the epitaxial passivation layer 404 is a continuous layer across a global surface 403 of the crystalline substrate 402, as is depicted in FIG. 4A. In another embodiment, however, the epitaxial passivation layer 404 is discontinuous between each of the plurality of alternating N-type 404A and P-type 404B emitter regions.

Referring again to FIG. 4A, in an embodiment, the light-receiving surface 401 is texturized. In an embodiment, a hydroxide-based wet etchant is employed to texturize the light receiving surface 401 of the crystalline substrate 402. In one embodiment, a texturized surface may be one which has a regular or an irregular shaped surface for scattering incoming light, decreasing the amount of light reflected off of the light receiving surface 401 of the solar cell. Referring again to FIG. 4A, additional embodiments can include formation of a passivation and/or anti-reflective coating (ARC) layers (shown collectively as layer 410) on the light-receiving surface 401.

It is to be appreciated that additional layers may be formed above the structure of FIG. 4A. As an example, FIG. 4B illustrates a cross-sectional view of the solar cell of FIG. 4A having a contact structure formed thereon, in accordance with an embodiment of the present disclosure. Referring to FIG. 4B, the solar cell 400 may further include a patterned anti-reflective coating layer 412 formed on the alternating N-type 404A and P-type 404B emitter regions. In one such embodiment, the anti-reflective coating layer 412 may be a layer of silicon nitride (SiN) or a layer of amorphous silicon/silicon nitride (a-Si/SiN), either of which may provide improved passivation for the interface between the crystalline substrate 402 and the epitaxial passivation layer 404.

Referring again to FIG. 4B, in an embodiment, conductive contacts 414 and 415 are formed in the patterned anti-reflective coating layer 412 and electrically contact the alternating emitter regions 404A and 404B. In one such embodiment, the conductive contacts 414 are P-type metal contacts (e.g., nickel or platinum) electrically contacting P-type regions in epitaxial layer 404, while the conductive contacts 415 are N-type metal contacts (e.g., aluminum) electrically contacting N-type regions in epitaxial layer 404. The resulting structure of FIG. 3B can be viewed as a completed or almost completed solar cell, which may be included in a solar module.

Energy band diagrams may be used to represent the effect of including an epitaxial passivation layer in the structure of FIG. 4A. As an example, FIG. 4C is an energy band diagram 450 for holes as a function of position for an exemplary epitaxial P-type GaP (p-GaP) passivation layer as applied to the structure of FIG. 4A, in accordance with an embodiment of the present disclosure. FIG. 4D is an energy band diagram 460 for electrons as a function of position for an exemplary epitaxial N-type GaP (n-GaP) passivation layer as applied to the structure of FIG. 4A, in accordance with an embodiment of the present disclosure.

Overall, although certain materials are described specifically above, some materials may be readily substituted with others with other such embodiments remaining within the spirit and scope of embodiments of the present disclosure. For example, in an embodiment, a different substrate material ultimately provides a solar cell substrate. In one such embodiment, a group III-V material substrate ultimately provides a solar cell substrate. Furthermore, it is to be appreciated that, where N+ and P+ type doping is described specifically, other embodiments contemplated include the opposite conductivity type, e.g., P+ and N+ type doping, respectively. Additionally, although reference is made significantly to back contact solar cell arrangements, it is to be appreciated that approaches described herein may have application to front contact solar cells as well. In other embodiments, the above described approaches can be applicable to manufacturing of other than solar cells. For example, manufacturing of light emitting diode (LEDs) may benefit from approaches described herein.

Thus, solar cells having epitaxial passivation layers have been disclosed.

Although specific embodiments have been described above, these embodiments are not intended to limit the scope of the present disclosure, even where only a single embodiment is described with respect to a particular feature. Examples of features provided in the disclosure are intended to be illustrative rather than restrictive unless stated otherwise. The above description is intended to cover such alternatives, modifications, and equivalents as would be apparent to a person skilled in the art having the benefit of this disclosure.

The scope of the present disclosure includes any feature or combination of features disclosed herein (either explicitly or implicitly), or any generalization thereof, whether or not it mitigates any or all of the problems addressed herein. Accordingly, new claims may be formulated during prosecution of this application (or an application claiming priority thereto) to any such combination of features. In particular, with reference to the appended claims, features from dependent claims may be combined with those of the independent claims and features from respective independent claims may be combined in any appropriate manner and not merely in the specific combinations enumerated in the appended claims.

1. A solar cell, comprising:
a crystalline substrate;
an epitaxial passivation layer disposed directly on the crystalline substrate; and
a plurality of alternating N-type and P-type emitter regions disposed on the epitaxial passivation layer.

2. The solar cell of claim 1, wherein the plurality of alternating N-type and P-type emitter regions is a plurality of alternating N-type and P-type semiconductor material regions.

3. The solar cell of claim 2, wherein the plurality of alternating N-type and P-type semiconductor material regions is a plurality of alternating phosphorous-doped polycrystalline silicon and boron-doped polycrystalline silicon regions.

4. The solar cell of claim 1, wherein the plurality of alternating N-type and P-type emitter regions is a plurality of alternating N-type and P-type metal regions.

5. The solar cell of claim 4, wherein the plurality of alternating N-type and P-type metal regions is a plurality of alternating aluminum (Al) and nickel (Ni) regions, or is a plurality of alternating aluminum (Al) and platinum (Pt) regions.

6. The solar cell of claim 1, wherein the epitaxial passivation layer is an epitaxial III-V material layer.

7. The solar cell of claim 6, wherein the epitaxial III-V material layer comprises a material selected from the group consisting of GaP, AlGaP, GaAs, InGaAs, GaN and AlGaN.

8. The solar cell of claim 1, wherein the epitaxial passivation layer is a continuous layer across a global surface of the crystalline substrate.

9. The solar cell of claim 1, wherein the epitaxial passivation layer is a patterned layer substantially aligned with a pattern of the plurality of alternating N-type and P-type emitter regions.

10. The solar cell of claim 1, wherein the crystalline substrate is a single crystalline silicon substrate having a crystal orientation selected from the group consisting of (100), (110), and (111).

11. A solar cell, comprising:
a crystalline substrate;
a first plurality of emitter regions of a first conductivity type disposed on a surface of the crystalline substrate, each of the first plurality of emitter regions comprising a doped polycrystalline silicon region disposed on an amorphous dielectric layer; and
a second plurality of emitter regions of a second conductivity type disposed on the surface of the crystalline substrate and alternating with the first plurality of emitter regions, each of the second plurality of emitter regions comprising a doped epitaxial material layer disposed directly on the crystalline substrate.

12. The solar cell of claim 11, wherein the doped polycrystalline silicon region of each of the first plurality of emitter regions comprises P-type doped polycrystalline silicon, and the doped epitaxial material layer is an N-type doped epitaxial material layer.

13. The solar cell of claim 11, wherein the doped polycrystalline silicon region of each of the first plurality of emitter regions comprises N-type doped polycrystalline silicon, and the doped epitaxial material layer is a P-type doped epitaxial material layer.

14. The solar cell of claim 11, wherein the doped epitaxial material layer is a continuous layer and is further disposed over the first plurality of emitter regions.

15. The solar cell of claim 11, wherein the doped epitaxial material layer is a doped epitaxial III-V material layer.

16. The solar cell of claim 15, wherein the doped epitaxial III-V material layer comprises a doped material selected from the group consisting of GaP, AlGaP, GaAs, InGaAs, GaN and AlGaN.

17. The solar cell of claim 11, wherein the crystalline substrate is a single crystalline silicon substrate having a crystal orientation selected from the group consisting of (100), (110), and (111).

18. A solar cell, comprising:
a crystalline substrate;
an epitaxial passivation layer disposed directly on the crystalline substrate; and
a plurality of alternating N-type and P-type emitter regions disposed in the epitaxial passivation layer.

19. The solar cell of claim 18, wherein the epitaxial passivation layer is an epitaxial III-V material layer.

20. The solar cell of claim 19, wherein the epitaxial III-V material layer comprises a material selected from the group consisting of GaP, AlGaP, GaAs, and In GaAs.

21.-23. (canceled)
